(19) United States
(12) Patent Application Publication
(10) Pub. No.: US 2016/0124240 A1
(43) Pub. Date: May 5, 2016

(54) SURFACE MOUNT DEVICE TYPE LASER MODULE

(71) Applicant: EVERREADY PRECISION IND. CORP., Kaohsiung City (TW)

(72) Inventors: JYH-LONG CHERN, TAIPEI CITY (TW); CHIH-MING YEN, New Taipei City (TW)

(21) Appl. No.: 14/595,818

(22) Filed: Jan. 13, 2015

(30) Foreign Application Priority Data
Oct. 31, 2014 (TW) 103137857
Oct. 31, 2014 (TW) 103219367

(51) Int. Cl. G02B 27/42; G02B 27/30; G02B 1/11; H01S 5/42

(52) U.S. Cl. CPC G02B 27/4233; H01S 5/423; G02B 27/30; G02B 1/11

(57) ABSTRACT

A surface mount device type laser module includes a housing, a vertical-cavity surface-emitting laser diode, a diffractive optical element and a base. The base is accommodated within the housing, and the vertical-cavity surface-emitting laser diode is integrated into the base. The base includes at least one surface transmission structure. The at least one surface transmission structure is exposed outside the base and the housing. An electronic signal is transmitted through the at least one surface transmission structure. Since the laser module is equipped with the diffractive optical element, the laser diffraction projection efficacy is achieved.

### FIELD OF THE INVENTION

The present invention relates to a laser module, and more particularly to a surface mount device type laser module.

### BACKGROUND OF THE INVENTION

FIG. 1 is a schematic perspective view illustrating a portion of the structure of a conventional laser module. The conventional laser module 1 has a TO-CAN package structure. Moreover, the conventional laser module 1 comprises a casing 11, a base 12, a laser diode 13, a photodiode 14, a heat sink 15, a first pin 16 and a second pin 17. The heat sink 15 and the photodiode 14 are fixed on the base 12. The laser diode 13 is disposed on the heat sink 15. The laser diode 13 and the photodiode 14 are connected with the first pin 16 and the second pin 17 through wires 18 and 19, respectively. The first pin 16 and the second pin 17 are penetrated downwardly through the base 12 and protruded outside. After the first pin 16 and the second pin 17 are penetrated through perforations of an external circuit board (not shown) and welded on the circuit board, electronic signals can be transmitted between the laser module 1 and the circuit board.

Moreover, the casing 11 is disposed on the base 12. The laser diode 13, the photodiode 14 and the heat sink 15 are covered by the casing 11. The casing 11 has an opening 111. A collimator lens 10 is disposed in the opening 111. After the laser diode 13 receives electric power through the first pin 16, the laser diode 13 provides a laser beam L1. The greater portion L11 of the laser beam L1 is propagated in the direction toward the opening 111 of the casing 11, transmitted through the collimator lens 10, and projected out. The smaller portion L12 of the laser beam L1 is projected on the photodiode 14 and optically detected by the photodiode 14. During the detecting process, the photodiode 14 generates detecting signals. These detecting signals are transmitted to the external circuitry through the second pin 17. According to the detecting signals, the subsequent controlling processes will be performed.

Generally, for welding the laser module 1 on the circuit board, the laser module 1 should be additionally equipped with the first pin 16 and the second pin 17. The first pin 16 and the second pin 17 have to be penetrated through the circuit board. Generally, the sizes of these pins need to be greater than a lowest limit. If these pins are smaller than the lowest limit, the pins are readily broken in response to an external force. Since the package structure of the laser module 1 cannot be effectively minimized, the applications of the laser module 1 on a handheld device, a wearable device or any other small-sized electronic device will be reduced.

Moreover, when the optical element (e.g. the collimator lens 10) is integrated into the conventional laser module 1, the structure of the optical element occupies a large space. Consequently, the structure of the optical element is also detrimental to miniaturization of the conventional laser module 1. Moreover, the conventional laser module 1 is usually equipped with a single light source. Consequently, the conventional laser module 1 cannot comply with the requirements of plural light sources or plural wavelengths of the modern electronic device. Under this circumstance, the development of the handheld device, the wearable device or the comparable electronic device is restricted. In other words, the conventional laser module 1 needs to be further improved.

### SUMMARY OF THE INVENTION

An object of the present invention provides a surface mount device type laser module (also referred as a SMD laser module), so that the overall volume of the electronic device with the surface mount device type laser module is reduced. Moreover, the laser module is equipped with a diffractive optical element, so that the laser diffraction projection efficacy is achieved. Moreover, the laser module may comprise plural vertical-cavity surface-emitting laser diode units. Consequently, the laser module can comply with the requirements of plural light sources or plural wavelengths of the modern electronic device. Under this circumstance, the development of the handheld device, the wearable device or the comparable electronic device is accelerated.

In accordance with an aspect of the present invention, there is provided a surface mount device type laser module. The surface mount device type laser module includes a housing, a base, a vertical-cavity surface-emitting laser diode unit and at least one optical element. The housing has an opening. The base is accommodated within the housing and includes at least one surface transmission structure. The at least one surface transmission structure is exposed outside the base and the housing. Moreover, at least one electronic signal is transmitted through the at least one surface transmission structure. The vertical-cavity surface-emitting laser diode unit is fixed on the base and providing at least one laser beam. The at least one optical element is fixed on the housing and disposed in the opening or near the opening. The vertical-cavity surface-emitting laser diode unit is arranged between the base and the at least one optical element. After a first portion of the at least one laser beam is projected to the at least one optical element and optically processed by the at least one optical element, the first portion of the at least one laser beam is projected out.

In an embodiment, the surface mount device type laser module further includes at least one photodiode unit. Moreover, at least a portion of the at least one laser beam is projected on the photodiode unit so as to be detected by the at least one photodiode unit.

In an embodiment, the photodiode unit is disposed on the base, and a second portion of the at least one laser beam is projected on the photodiode unit.

In an embodiment, the photodiode unit is disposed outside the base, and the surface mount device type laser module further includes an optical guide element. The at least a portion of the at least one laser beam is guided by the optical guide element and projected on the photodiode unit.

In an embodiment, a center laser beam of the first portion of the at least one laser beam is emitted from a center position of a lighting zone of the vertical-cavity surface-emitting laser diode unit and propagated in a direction toward an optical center of the at least one optical element.

In an embodiment, the at least one optical element includes a collimator optical element, wherein the first portion of the at least one laser beam is collimated by the collimator optical element.

In an embodiment, the at least one optical element further comprises a diffractive optical element. After the first portion of the at least one laser beam is transmitted through the collimator optical element, the first portion of the at least one laser beam is shaped by the diffractive optical element and projected out.

In an embodiment, a distance between a first optical axis of the collimator optical element and a second optical axis of the diffractive optical element is smaller than 0.2 mm.

In an embodiment, an angle between a first optical axis of the collimator optical element and a second optical axis of the diffractive optical element is smaller than 2.5 degrees.

In an embodiment, the collimator optical element and the diffractive optical element are integrated as a single optical structure.

In an embodiment, the collimator optical element has an effective focal length f, wherein f<1.5 mm.

In an embodiment, the collimator optical element has a numerical aperture N.A., wherein N.A.<06.

In an embodiment, the surface mount device type laser module further includes a second vertical-cavity surface-emitting laser diode unit, wherein plural laser beams from the vertical-cavity surface-emitting laser diode unit and the second vertical-cavity surface-emitting laser diode unit are collimated by the collimator optical element.

In an embodiment, the at least one optical element is coated with an anti-reflection coating.

In an embodiment, the at least one surface transmission structure comprises at least one contact pad or at least one pin.

In an embodiment, the vertical-cavity surface-emitting laser diode unit comprises plural laser diode chips, wherein the plural laser diode chips provide plural laser beams.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic perspective view illustrating a portion of the structure of a conventional laser module;

FIG. 2 is a schematic perspective view illustrating the outer appearance of a surface mount device type laser module according to a first embodiment of the present invention;

FIG. 3 is a schematic exploded view illustrating the surface mount device type laser module of FIG. 2;

FIG. 4 is a schematic front view illustrating a portion of the surface mount device type laser module of FIG. 2;

FIG. 5 is a schematic front view illustrating the outer appearance of a portion of a surface mount device type laser module according to a second embodiment of the present invention; and

FIG. 6 is a schematic front view illustrating the outer appearance of a portion of a surface mount device type laser module according to a third embodiment of the present invention.

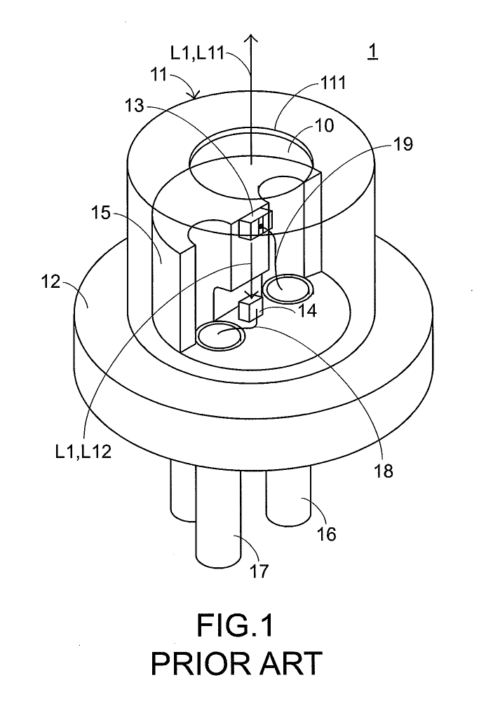

### DETAILED DESCRIPTION OF THE PREFERRED EMBODIMENT

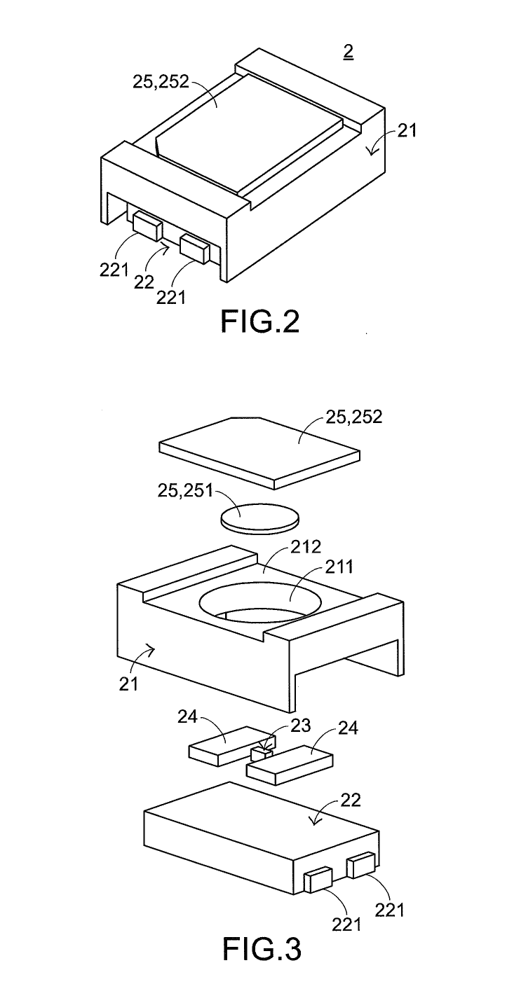

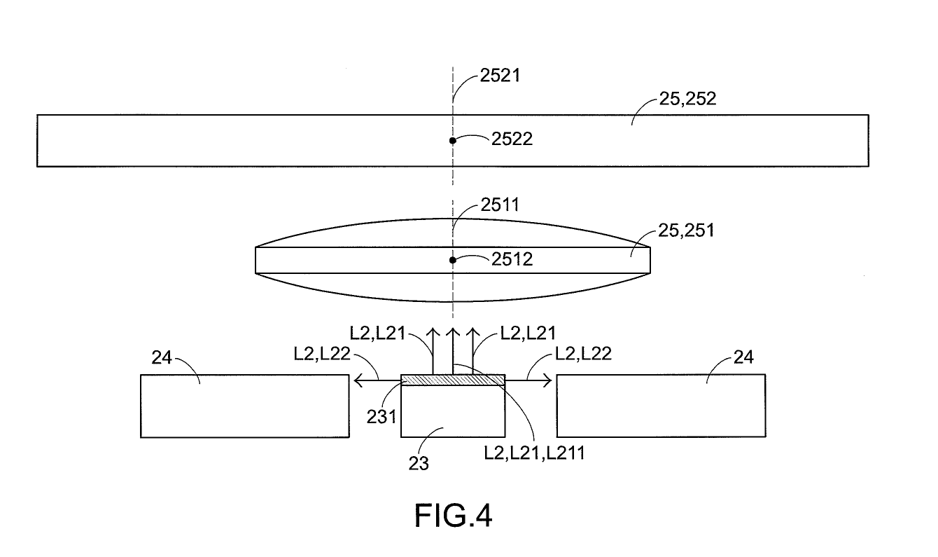

Please refer to FIGS. 2-4. FIG. 2 is a schematic perspective view illustrating the outer appearance of a surface mount device type laser module according to an embodiment of the present invention. FIG. 3 is a schematic exploded view illustrating the surface mount device type laser module of FIG. 2. FIG. 4 is a schematic front view illustrating a portion of the surface mount device type laser module of FIG. 2. The surface mount device type laser module 2 comprises a housing 21, a base 22, a vertical-cavity surface-emitting laser diode unit (VCSEL) 23, two photodiode units (PD) 24 and plural optical elements 25. The base 22 is accommodated within the housing 21. The base 22 may support one or more vertical-cavity surface-emitting laser diode units 23 and the photodiode units 24. Moreover, the base 22 may provide a flat surface or a recess with a bottom surface in order to fix the one or more vertical-cavity surface-emitting laser diode units 23 and the photodiode units 24. The base 22 comprises plural surface transmission structures 221. The plural surface transmission structures 221 are exposed outside the base 22 and the housing 21. The thickness of the surface transmission structure 221 is much smaller than the thickness of the base 22 and the thickness of the housing 21. The plural surface transmission structures 221 may be welded on a circuit board (not shown) through solder paste. Consequently, the electronic signals from the surface mount device type laser module 2 may be transmitted to the circuit board through the surface transmission structures 221, and the electronic signals from the circuit board may be transmitted to the surface mount device type laser module 2 through the surface transmission structures 221. The examples of the surface transmission structures 221 include but are not limited to contact pads or pins. Moreover, in the above drawings, the base 22 has a rectangular shape. It is noted that the shape of the base 22 may be varied according to the practical requirements.

The housing 21 and/or the substrate 22 may be used for dissipating heat. The housing 21 has an opening 211. In this embodiment, the opening 211 has a circular shape. It is noted that the shape and the size of the opening 211 are not restricted to those shown in the drawings. A laser beam inside the opaque housing 21 may be transmitted through the opening 211 and projected out. Moreover, the plural optical elements 25 are disposed in the opening 211 or arranged near the opening 211. The vertical-cavity surface-emitting laser diode unit 23 comprises a laser diode chip 231. The vertical-cavity surface-emitting laser diode unit 23 is arranged between the two photodiode unit 24 in the horizontal direction, and the vertical-cavity surface-emitting laser diode unit 23 is arranged between the base 22 and the plural optical elements 25 in the vertical direction. After the vertical-cavity surface-emitting laser diode unit 23 receive electric power (for example through the surface transmission structures 221), the vertical-cavity surface-emitting laser diode unit 23 may provide plural laser beams L2. A first-portion (i.e. the main-portion) laser beam L21 of the plural laser beams L2 is propagated in the direction toward the opening 211 of the housing 21. After the first-portion laser beam L21 is optically processed by the plural optical elements 25, the processed laser beam is projected out. Moreover, a second-portion (i.e. the minor-portion) laser beam L22 of the plural laser beams L2 is propagated in the direction toward the photodiode unit 24, so that the second-portion laser beam L22 is optically detected by the photodiode unit 24. During the detecting process, the photodiode unit 24 generates detecting signals. These detecting signals are transmitted to the external circuitry through the surface transmission structures 221. According to the detecting signals, the subsequent controlling processes will be performed.

In this embodiment, the plural optical elements 25 comprise a collimator optical element 251 and a diffractive optical element (DOE) 252. The collimator optical element 251 is fixed in the opening 211 of the housing 21. The diffractive optical element 252 is disposed over the collimator optical element 251 and fixed in a concave structure 212 of the housing 21. The collimator optical element 251 is used for collimating the first-portion laser beam L21 from the vertical-cavity surface-emitting laser diode unit 23. After the first-portion laser beam L21 is transmitted through the collimator optical element 251, the first-portion laser beam L21 is introduced into the diffractive optical element 252 at a preferable incident angle. Consequently, the first-portion laser beam L21 through the collimator optical element 251 is shaped by the diffractive optical element 252 and shaped laser beam is projected out. Generally, by designing the texture of the diffractive optical element 252, the surface mount device type laser module 2 can be used as a generator for generating specified textured light and achieving the laser diffraction projection efficacy. The examples of the diffractive optical element are well known to those skilled in the art, and are not redundantly described herein.

Preferably, for increasing the light transmittance, the collimator optical element 251 and/or the diffractive optical element 252 may be coated with anti-reflection coatings. In addition, the effective focal length (f) and the numerical aperture (N.A.) of the collimator optical element 251 comply with the following relationships: f<1.5 mm and N.A.<0.6. The relationships are not restricted. The deviation amount between the optical axis 2511 of the collimator optical element 251 and the optical axis 2521 (or a second optical axis) of the diffractive optical element 252 is smaller than 0.2 mm, and the angle between the optical axis 2511 of the collimator optical element 251 and the optical axis 2521 of the diffractive optical element 252 is smaller than 2.5 degrees. More preferably, a center laser beam L211 of the first-portion laser beam L21 is emitted from a center position of a lighting zone of the vertical-cavity surface-emitting laser diode unit 23. The center laser beam L211 is propagated in the direction toward the optical centers 2512 and 2522 of these optical elements 25. Generally, the laser beam passing through the optical center does not suffer from any deviation.

In another embodiment, the collimator optical element 251 and the diffractive optical element 252 are integrated as a single optical structure. Optionally, a plate (not shown) is arranged between the collimator optical element 251 and the diffractive optical element 252. Moreover, for reducing the integration error between the collimator optical element 251 and the diffractive optical element 252, the material of the plate is different from the materials of the collimator optical element 251 and the diffractive optical element 252. Consequently, the transmitting direction of the first-portion laser beam L21 is corrected and the light transmittance is enhanced.

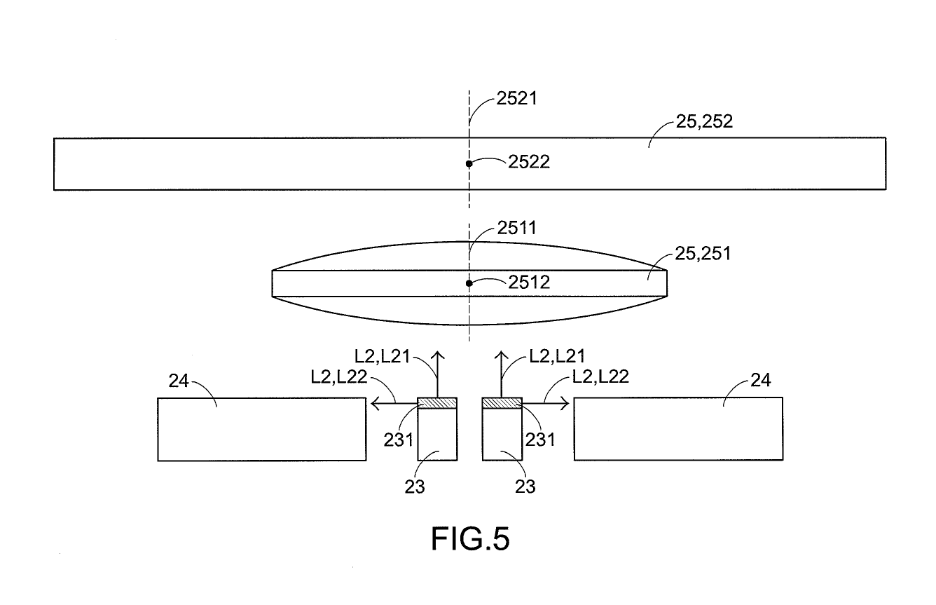

It is noted that numerous modifications and alterations may be made while retaining the teachings of the invention. In the above embodiment, the surface mount device type laser module only comprises a single vertical-cavity surface-emitting laser diode unit 23. In a variant example, as shown in FIG. 5, the surface mount device type laser module comprises plural vertical-cavity surface-emitting laser diode units 23 and plural photodiode units 24, which are disposed on proper positions of the base 22. The plural first-portion laser beams L21 from the plural vertical-cavity surface-emitting laser diode units 23 are collimated by the collimator optical element 251 and then directed to the diffractive optical element 252. Moreover, in case that a single vertical-cavity surface-emitting laser diode unit 23 comprises plural laser diode chips 231, the object of the present invention is achievable by using the similar approach. Moreover, the number of the collimator optical element 251 is not restricted. For example, in some other embodiments, the surface mount device type laser module may comprise plural collimator optical elements 251 corresponding to the plural vertical-cavity surface-emitting laser diode units 23.

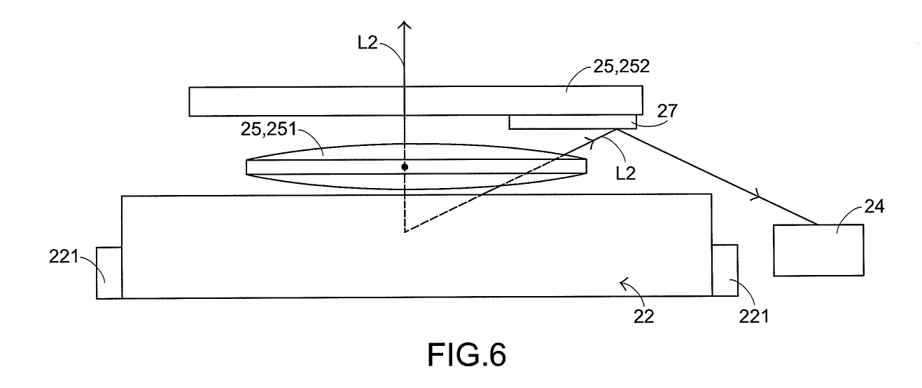

In the above embodiment, the photodiode unit 24 of the surface mount device type laser module is disposed on the base 22. In a variant example, as shown in FIG. 6, the photodiode unit 24 is disposed outside the base 22. In addition, the surface mount device type laser module further comprises an optical guide element 27. After the laser beam L2 is projected on the optical guide element 27, the laser beam L2 is guided by the optical guide element 27 and propagated in the direction toward the photodiode unit 24, so that the laser beam L2 is optically detected by the photodiode unit 24. An example the photodiode unit 24 includes but is not limited to a planar photodiode unit or a dome type photodiode unit. An example of the optical guide element 27 includes but is not limited to a reflective element, a diffractive element or a diffractive element, which is formed by applying a coating or forming a film.

Since the laser module is a surface mount device type (SMD) laser module, the overall volume is effectively reduced. Consequently, the laser module is suitably applied to a handheld device, a wearable device or any other small-sized electronic device. Moreover, the laser module is equipped with the diffractive optical element, so that the laser diffraction projection efficacy is achieved. Moreover, the laser module may comprise plural vertical-cavity surface-emitting laser diode units. Consequently, the laser module can comply with the requirements of plural light sources or plural wavelengths of the modern electronic device. Under this circumstance, the development of the handheld device, the wearable device or the comparable electronic device is accelerated.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A surface mount device type laser module, comprising:
a housing having an opening;
a base accommodated within the housing and comprising at least one surface transmission structure, wherein the at least one surface transmission structure is exposed outside the base and the housing, and at least one electronic signal is transmitted through the at least one surface transmission structure;
a vertical-cavity surface-emitting laser diode unit fixed on the base and providing at least one laser beam; and
at least one optical element fixed on the housing and disposed in the opening or near the opening, wherein the vertical-cavity surface-emitting laser diode unit is arranged between the base and the at least one optical element, wherein after a first portion of the at least one laser beam is projected to the at least one optical element and optically processed by the at least one optical element, the first portion of the at least one laser beam is projected out.

2. The surface mount device type laser module according to claim 1, further comprising at least one photodiode unit, wherein at least a portion of the at least one laser beam is projected on the photodiode unit so as to be detected by the at least one photodiode unit.

3. The surface mount device type laser module according to claim 1, wherein the photodiode unit is disposed on the base, and a second portion of the at least one laser beam is projected on the photodiode unit.

4. The surface mount device type laser module according to claim 2, wherein the photodiode unit is disposed outside the base, and the surface mount device type laser module further comprises an optical guide element, wherein the at least a portion of the at least one laser beam is guided by the optical guide element and projected on the photodiode unit.

5. The surface mount device type laser module according to claim 1, wherein a center laser beam of the first portion of the at least one laser beam is emitted from a center position of a lighting zone of the vertical-cavity surface-emitting laser diode unit and propagated in a direction toward an optical center of the at least one optical element.

6. The surface mount device type laser module according to claim 1, wherein the at least one optical element comprises a collimator optical element, wherein the first portion of the at least one laser beam is collimated by the collimator optical element.

7. The surface mount device type laser module according to claim 6, wherein the at least one optical element further comprises a diffractive optical element, wherein after the first portion of the at least one laser beam is transmitted through the collimator optical element, the first portion of the at least one laser beam is shaped by the diffractive optical element and projected out.

8. The surface mount device type laser module according to claim 7, wherein a distance between a first optical axis of the collimator optical element and a second optical axis of the diffractive optical element is smaller than 0.2 mm.

9. The surface mount device type laser module according to claim 7, wherein an angle between a first optical axis of the collimator optical element and a second optical axis of the diffractive optical element is smaller than 2.5 degrees.

10. The surface mount device type laser module according to claim 7, wherein the collimator optical element and the diffractive optical element are integrated as a single optical structure.

11. The surface mount device type laser module according to claim 6, wherein the collimator optical element has an effective focal length f, wherein f<1.5 mm.

12. The surface mount device type laser module according to claim 6, wherein the collimator optical element has a numerical aperture N.A., wherein N.A.<0.6.

13. The surface mount device type laser module according to claim 6, further comprising a second vertical-cavity surface-emitting laser diode unit, wherein plural laser beams from the vertical-cavity surface-emitting laser diode unit and the second vertical-cavity surface-emitting laser diode unit are collimated by the collimator optical element.

14. The surface mount device type laser module according to claim 1, wherein the at least one optical element is coated with an anti-reflection coating.

15. The surface mount device type laser module according to claim 1, wherein the at least one surface transmission structure comprises at least one contact pad or at least one pin.

16. The surface mount device type laser module according to claim 1, wherein the vertical-cavity surface-emitting laser diode unit comprises plural laser diode chips, wherein the plural laser diode chips provide plural laser beams.
